(19) United States
(12) Patent Application Publication
(10) Pub. No.: US 2015/0249189 A1
(43) Pub. Date: Sep. 3, 2015

(54) Semiconductor Multilayer Structure And Semiconductor Element

(71) Applicants: TAMURA CORPORATION, Tokyo (JP); KOHA CO., LTD., Tokyo (JP)

(72) Inventor: Shinkuro SATO, Tokyo (JP)

(21) Appl. No.: 14/633,084

(22) Filed: Feb. 26, 2015

(30) Foreign Application Priority Data
Feb. 28, 2014 (JP) 2014-039784

(51) Int. Cl. H01L 33/32; H01L 33/16; C30B 29/16; H01L 33/12; C30B 15/34; C30B 15/36

(52) U.S. Cl. CPC H01L 33/32; C30B 15/34; C30B 15/36; C30B 29/16; H01L 33/12; H01L 33/16

(57) ABSTRACT

A semiconductor multilayer structure includes a β-Ga₂O₃-based single crystal substrate including a dislocation density on a main surface of not more than 1×10³/cm²; and a nitride semiconductor layer including an AlₓGa_{y}In_{z}N (0≦x≦1, 0≦y≦1, 0≦z≦1, x+y+z=1) crystal epitaxially grown on the β-Ga₂O₃-based single crystal substrate.

The present application is based on Japanese patent application No. 2014-039784 filed on Feb. 28, 2014, the entire contents of which are incorporated herein by reference.

### BACKGROUND OF THE INVENTION

1. Field of the Invention

The invention relates to a semiconductor multilayer structure and a semiconductor element.

2. Description of the Related Art

A semiconductor multilayer structure is known which has a β-Ga₂O₃ single crystal substrate and a nitride semiconductor layer formed thereon by epitaxial growth (see e.g. JP-A-2013-251439).

JP-A-2013-251439 also discloses a semiconductor element, such as LED element, which is formed by using the semiconductor multilayer structure.

### SUMMARY OF THE INVENTION

In manufacturing a semiconductor element such as a light-emitting element and a transistor by using the semiconductor multilayer structure which has the β-Ga₂O₃-based single crystal substrate and the nitride semiconductor layer formed thereon by epitaxial growth, it is important to grow a high-quality nitride semiconductor layer on the β-Ga₂O₃-based single crystal substrate in order to reduce a leakage current in the semiconductor device and to improve the yield and the reliability.

It is an object of the invention to provide a semiconductor multilayer structure that includes a β-Ga₂O₃-based single crystal substrate and a nitride semiconductor layer with a high crystal quality formed thereon, as well as a semiconductor element including the semiconductor multilayer structure.

According to one embodiment of the invention, a semiconductor multilayer structure as set forth in [1] to [3] below is provided.

[1] A semiconductor multilayer structure, comprising:

a β-Ga₂O₃-based single crystal substrate comprising a dislocation density on a main surface of not more than 1×10³/cm²; and

a nitride semiconductor layer comprising an AlₓGa_{y}In_{z}N (0≦x≦1, 0≦y≦1, 0≦z≦1, x+y+z=1) crystal epitaxially grown on the β-Ga₂O₃-based single crystal substrate.

[2] The semiconductor multilayer structure according to [1], further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.
[3] The semiconductor multilayer structure according to [1] or [2], wherein the nitride semiconductor layer comprises a GaN crystal.

According to another embodiment of the invention, a semiconductor element as set forth in [4] below is provided.

[4] A semiconductor element, comprising the semiconductor multilayer structure according to any one of [1] to [3].

### Effects of the Invention

According to one embodiment of the invention, a semiconductor multilayer structure can be provided that includes a β-Ga₂O₃-based single crystal substrate and a nitride semiconductor layer with a high crystal quality formed thereon, as well as a semiconductor element including the semiconductor multilayer structure.

### BRIEF DESCRIPTION OF THE DRAWINGS

Next, the present invention will be explained in more detail in conjunction with appended drawings, wherein:

FIG. 1 is a vertical cross-sectional view showing a semiconductor multilayer structure in a first embodiment;

FIG. 2 is a vertical cross-sectional view showing an EFG crystal manufacturing apparatus in the first embodiment;

FIG. 3 is a perspective view showing a state during growth of a β-Ga₂O₃-based single crystal 32 in the first embodiment;

FIG. 4 is a perspective view showing a state of growing a β-Ga₂O₃-based single crystal 36 to be cut into a seed crystal; FIGS. 5A and 5B are optical microscope observation images showing a surface state of a β-Ga₂O₃ single crystal substrate containing dislocations of about 1.3×10³/cm² and a surface state of a GaN layer epitaxially grown on a main surface thereof;

FIGS. 6A and 6B are optical microscope observation images showing a surface state of a β-Ga₂O₃ single crystal substrate containing dislocations of about 1.7×10³/cm² and a surface state of a GaN layer epitaxially grown on a main surface thereof;

FIGS. 7A and 7B are optical microscope observation images showing a surface state of a β-Ga₂O₃ single crystal substrate containing dislocations of not more than 1×10²/cm² and a surface state of a GaN layer epitaxially grown on a main surface thereof;

FIG. 8 is a graph showing a relation between a pit-defect density on a surface of the β-Ga₂O₃ single crystal substrate and a hillock-defect density on a surface of the GaN layer;

FIGS. 9A and 9B are optical microscope observation images showing a position on a surface of the GaN layer at which TEM observation is performed;

FIG. 10 is a TEM observed image showing a cross section of the β-Ga₂O₃ single crystal substrate with the GaN layer in the region shown in FIGS. 9A and 9B;

FIG. 11 is a vertical cross-sectional view showing an LED element in a second embodiment;

FIGS. 12A, 12B and 12C are optical microscope observation images of surfaces of LED elements, respectively showing an LED element formed using a hillock-type defect-free region of a nitride semiconductor layer 42, an LED element formed using a region with a few hillock-type defects and an LED element formed using a region with many hillock-type defects; and

FIG. 13 is a graph showing a relation between hillock-defect density and magnitude of leakage current in the LED element.

### DETAILED DESCRIPTION OF THE PREFERRED EMBODIMENTS

### First Embodiment

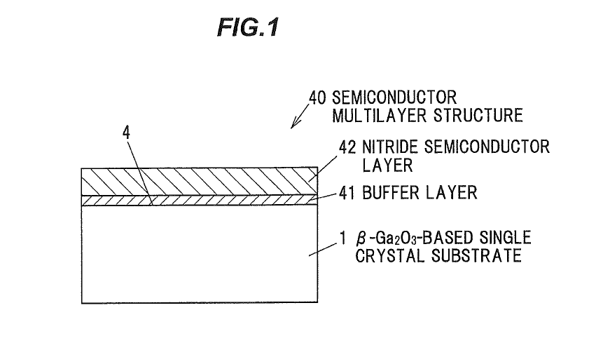

(Configuration of semiconductor multilayer structure) FIG. 1 is a vertical cross-sectional view showing a semiconductor multilayer structure 40 in the first embodiment. The semiconductor multilayer structure 40 has a β-Ga₂O₃-based single crystal substrate 1 and a nitride semiconductor layer 42 which is formed on a main surface 4 of the β-Ga₂O₃-based single crystal substrate 1 by epitaxial crystal growth. It is preferable to also provide a buffer layer 41 between the β-Ga₂O₃-based single crystal substrate 1 and the nitride semiconductor layer 42 as shown in FIG. 1 to reduce lattice mismatch between the β-Ga₂O₃-based single crystal substrate 1 and the nitride semiconductor layer 42.

The β-Ga₂O₃-based single crystal substrate 1 is formed of a β-Ga₂O₃-based single crystal. The β-Ga₂O₃-based single crystal here is a β-Ga₂O₃ single crystal, or a β-Ga₂O₃ single crystal doped with an element such as Mg, Fe, Cu, Ag, Zn, Cd, Al, In, Si, Ge, Sn or Nb.

The β-Ga₂O₃-based crystal has a β-gallia structure belonging to the monoclinic system and typical lattice constants of the β-Ga₂O₃ crystal not containing impurities are a₀=12.23 Å, b₀=3.04 Å, c₀=5.80 Å, α=γ=90° and β=103.8°.

The orientation of a main surface of the β-Ga₂O₃-based single crystal substrate 1 is not limited to a specific orientation and is, e.g., (-201), (101), (310), (3-10) or (100). The thickness of the β-Ga₂O₃-based single crystal substrate 1 is, e.g., 700 μm.

Meanwhile, a dislocation density on the main surface 4 of the β-Ga₂O₃-based single crystal substrate 1 is not more than 1×10³/cm² regardless of plane orientation of the main surface 4, which means that dislocations contained are very few. This dislocation density is obtained based on a pit-defect density on the main surface 4 of the β-Ga₂O₃-based single crystal substrate 1. The inventors of the present application have confirmed that the dislocation density and the pit-defect density on the main surface 4 of the β-Ga₂O₃-based single crystal substrate 1 are substantially the same.

The pit-defect density mentioned above is measured on an optical microscope observation image taken at the center of the (-201)-oriented main surface 4 of the β-Ga₂O₃-based single crystal substrate 1. Also on the main surface 4 of the β-Ga₂O₃-based single crystal substrate 1 of which plane orientation is other than (-201), e.g., is (101), (310) or (3-10), the dislocation density is substantially the same as that on the (-201)-oriented main surface 4.

When dislocations are present on a surface of a β-Ga₂O₃-based single crystal substrate, dislocation portions are generally preferentially-etched and the preferentially-etched portions on the substrate surface appear as pit-type defects after a polishing process such as CMP (Chemical Mechanical Polishing) or after cleaning with an acid. In addition, even if pit-type defects do not appear in the processes mentioned above, it is considered that pit-type defects are formed since the dislocation portions are etched by a reducing gas such as NH₃ or N₂ used for epitaxially growing a nitride semiconductor layer on the β-Ga₂O₃-based single crystal substrate.

Hillock-type defects (raised portions with a height of about 1 μm) are formed on a surface of a nitride semiconductor layer grown on pit-type detects of the surface of the β-Ga₂O₃-based single crystal substrate, as described later. The nitride semiconductor layer with hillock-type defects has only a small area available for manufacture of semiconductor element since use of hillock-defect portions causes problems such as leakage and should be avoided, and this leads to a decrease in yield.

There is a correspondence relation between the pit-defect density on the surface of the β-Ga₂O₃-based single crystal substrate 1 and the hillock-defect density on the surface of the nitride semiconductor layer 42 as described later, and it is required to use the β-Ga₂O₃-based single crystal substrate 1 with less pit-type defects, i.e., with less dislocations to form the nitride semiconductor layer 42 with less pit-type defects. In addition, the hillock-defect density on the nitride semiconductor layer 42 needs to be not more than 1×10³/cm² for manufacture of light-emitting elements or semiconductor elements such as transistor.

The buffer layer 41 is formed of an AlₓGa_{y}In_{z}N (0≦x≦1, 0≦y≦1, 0≦z≦1, x+y+z=1) crystal. On the β-Ga₂O₃-based single crystal substrate 1, the buffer layer 41 may be formed in an island pattern or in the form of film. The buffer layer 41 may contain a conductive impurity such as Si.

In addition, among AlₓGa_{y}In_{z}N crystals, an AlN crystal (x=1, y=z=0) is particularly preferable to form the buffer layer 41. When the buffer layer 41 is formed of the AlN crystal, adhesion between the β-Ga₂O₃-based single crystal substrate 1 and the nitride semiconductor layer 42 is further increased. The thickness of the buffer layer 41 is, e.g., 1 to 5 nm.

The buffer layer 41 is formed on the main surface 4 of the β-Ga₂O₃-based single crystal substrate 1 by, e.g., epitaxially growing an AlₓGa_{y}In_{z}N (0≦x≦1, 0≦y≦1, 0≦z≦1, x+y+z=1) crystal at a growth temperature of about 370 to 500° C.

The nitride semiconductor layer 42 is formed of an AlₓGa_{y}In_{z}N (0≦x≦1, 0≦y≦1, 0≦z≦1, x+y+z=1) crystal and is particularly preferably formed of a GaN crystal (y=1, x=z=0) from which a high-quality crystal is easily obtained. The thickness of the nitride semiconductor layer 42 is, e.g., 5 μm. The nitride semiconductor layer 42 may contain a conductive impurity such as Si.

The nitride semiconductor layer 42 is formed on the main surface 4 of the β-Ga₂O₃-based single crystal substrate 1 via the buffer layer 41 by, e.g., epitaxially growing an AlₓGa_{y}In_{z}N (0≦x≦1, 0≦y≦1, 0≦z≦1, x+y+z−1) crystal at a growth temperature of about 1000° C.

(Method of Manufacturing β-Ga₂O₃-Based Single Crystal Substrate)

The following is an example of a method of manufacturing the β-Ga₂O₃-based single crystal substrate 1 with low dislocation density.

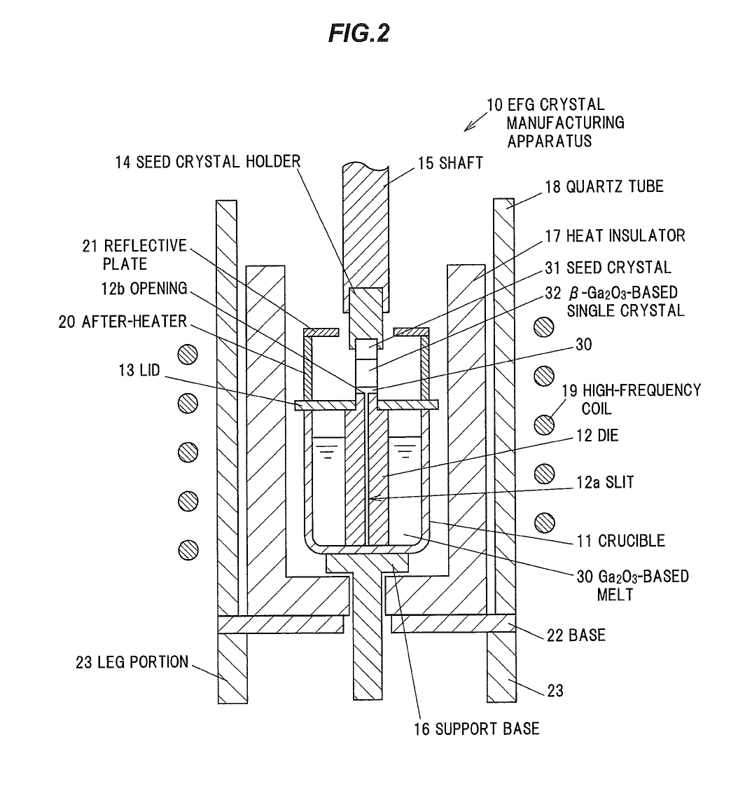

FIG. 2 is a vertical cross-sectional view showing an EFG (Edge Defined Film Fed Growth) crystal manufacturing apparatus 10 in the first embodiment.

The EFG crystal manufacturing apparatus 10 has a crucible 11 which is placed in a quartz tube 18 and contains Ga₂O₃-based melt 30, a die 12 placed in the crucible 11 and having a slit 12a, a lid 13 covering an opening of the crucible 11 so that the top surface of the die 12 including an opening 12b is exposed, a seed crystal holder 14 for holding a seed crystal 31, a shaft 15 vertically movably supporting the seed crystal holder 14, a support base 16 for placing the crucible 11, a heat insulator 17 provided along an inner wall of the quartz tube 18, a high-frequency coil 19 for high-frequency induction heating provided around the quartz tube 18, a base 22 for supporting the quartz tube 18 and the heat insulator 17, and leg portions 23 attached to the base 22.

The EFG crystal manufacturing apparatus 10 further includes an after-heater 20 and a reflective plate 21. The after-heater 20 is formed of Ir, etc., and is provided to surround a region above the crucible 11 where a β-Ga₂O₃-based single crystal 32 is grown. The reflective plate 21 is formed of Ir, etc., and is provided, like a lid, on the after-heater 20.

The crucible 11 contains the Ga₂O₃-based melt 30 which is obtained by melting a Ga₂O₃-based raw material. The crucible 11 is formed of a highly heat-resistant material such as Ir capable of containing the Ga₂O₃-based melt 30.

The die 12 has the slit 12a to draw up the Ga₂O₃-based melt 30 in the crucible 11 by capillary action. The die 12 is formed of a highly heat-resistant material such as Ir in the same manner as the crucible 11.

The lid 13 prevents the high-temperature Ga₂O₃-based melt 30 from evaporating from the crucible 11 and further prevents the evaporated substances from attaching to members located outside of the crucible 11.

The high-frequency coil 19 is helically arranged around the quartz tube 18 and inductively heats the crucible 11 and the after-heater 20 by a high-frequency current which is supplied from a non-illustrated power source. This causes the Ga₂O₃-based raw material in the crucible to melt and the Ga₂O₃-based melt 30 is thereby obtained.

The heat insulator 17 is provided around the crucible 11 with a predetermined gap. The heat insulator 17 retains heat and is thus capable of suppressing a rapid temperature change of the inductively-heated crucible 11, etc.

The after-heater 20 generates heat by induction heating and the reflective plate 21 downwardly reflects heat radiated from the after-heater 20 and the crucible 11. The present inventors confirmed that the after-heater 20 is capable of reducing radial (horizontal) temperature gradient in a hot zone and the reflective plate 21 is capable of reducing temperature gradient in a crystal growth direction in the hot zone.

It is possible to reduce the dislocation density of the β-Ga₂O₃-based single crystal 32 by providing the after-heater 20 and the reflective plate 21 on the EFG crystal manufacturing apparatus 10. This allows the β-Ga₂O₃-based single crystal substrate 1 with low dislocation density to be obtained from the β-Ga₂O₃-based single crystal 32.

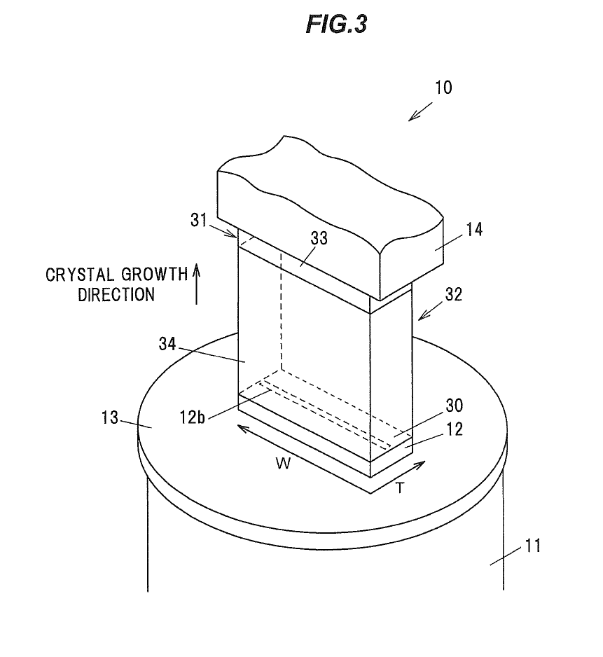

FIG. 3 is a perspective view showing a state during growth of the β-Ga₂O₃-based single crystal 32 in the first embodiment. Illustrations of members around the β-Ga₂O₃-based single crystal 32 are omitted in FIG. 3.

To grow the β-Ga₂O₃-based single crystal 32, firstly, the Ga₂O₃-based melt 30 in the crucible 11 is drawn up to the opening 12b of the die 12 through the slit 12a of the die 12, and the seed crystal 31 is then brought into contact with the Ga₂O₃-based melt 30 present in the opening 12b of the die 12. Next, the seed crystal 31 in contact with the Ga₂O₃-based melt 30 is pulled vertically upward, thereby growing the β-Ga₂O₃-based single crystal 32.

The seed crystal 31 is a β-Ga₂O₃-based single crystal which does not have or hardly has twinning planes. The seed crystal 31 has substantially the same width and thickness as the β-Ga₂O₃-based single crystal 32 to be grown. Thus, it is possible to grow the β-Ga₂O₃-based single crystal 32 without broadening a shoulder thereof in a width direction W and a thickness direction T.

Since the growth of the β-Ga₂O₃-based single crystal 32 does not involve a process of broadening a shoulder in the width direction W, twinning of the β-Ga₂O₃-based single crystal 32 is suppressed. Meanwhile, unlike the broadening of shoulder in the width direction W, twins are less likely to be formed when broadening the shoulder in the thickness direction T, and thus the growth of the β-Ga₂O₃-based single crystal 32 may involve a process of broadening a shoulder in the thickness direction T. However, in the case that the process of broadening a shoulder in the thickness direction T is not performed, substantially the entire β-Ga₂O₃-based single crystal 32 becomes a plate-shaped region which can be cut into substrates and this allows the substrate manufacturing cost to be reduced. Therefore, it is preferable to not perform the process of broadening a shoulder in the thickness direction T but to use a thick seed crystal 31 to ensure sufficient thickness of the β-Ga₂O₃-based single crystal 32 as shown in FIG. 3.

The orientation of a horizontally-facing surface 33 of the seed crystal 31 coincides with that of a main surface 34 of the β-Ga₂O₃-based single crystal 32. Therefore, for obtaining the β-Ga₂O₃-based single crystal substrate 1 having, e.g., the (-201)-oriented main surface 4 from the β-Ga₂O₃-based single crystal 32, the β-Ga₂O₃-based single crystal 32 is grown in a state that the surface 33 of the seed crystal 31 is oriented to (-201).

Next, a method in which a wide seed crystal 31 with a width equivalent to the β-Ga₂O₃-based single crystal 32 is formed using a quadrangular prism-shaped narrow-width seed crystal will be described.

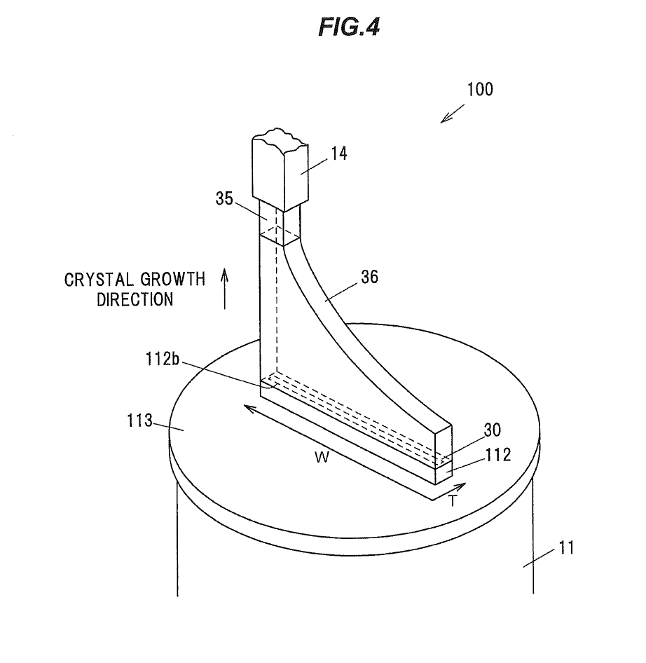

FIG. 4 is a perspective view showing a state of growing the β-Ga₂O₃-based single crystal 36 to be cut into the seed crystal 31.

The seed crystal 31 is cut from a region of the β-Ga₂O₃-based single crystal 36 not having or hardly having twinning planes. Therefore, a width (a size in the width direction W) of the β-Ga₂O₃-based single crystal 36 is larger than the width of the seed crystal 31.

Meanwhile, a thickness (a size in the thickness direction T) of the β-Ga₂O₃-based single crystal 36 may be smaller than the thickness of the seed crystal 31. In such a case, the seed crystal 31 is not cut directly from the β-Ga₂O₃-based single crystal 36. Instead, a β-Ga₂O₃-based single crystal is firstly grown from a seed crystal cut from the β-Ga₂O₃-based single crystal 36 while broadening a shoulder in the thickness direction T and is then cut into the seed crystal 31.

For growing the β-Ga₂O₃-based single crystal 36, it is possible to use an EFG crystal manufacturing apparatus 100 which has substantially the same structure as the EFG crystal manufacturing apparatus 10 used for growing the β-Ga₂O₃-based single crystal 32.

However, width, or width and thickness, of a die 112 of the EFG crystal manufacturing apparatus 100 is/are different from that/those of the die 12 of the EFG crystal manufacturing apparatus 10 since the width, or width and thickness, of the β-Ga₂O₃-based single crystal 36 is/are different from that/those of the β-Ga₂O₃-based single crystal 32. The size of an opening 112b of the die 112 may be the same as the opening 12b of the die 12.

A seed crystal 35 is a quadrangular prism-shaped β-Ga₂O₃-based single crystal with a smaller width than the β-Ga₂O₃-based single crystal 36 to be grown.

To grow the β-Ga₂O₃-based single crystal 36, firstly, the Ga₂O₃-based melt 30 in the crucible 11 is drawn up to the opening 112b of the die 112 through a slit of the die 112, and the seed crystal 35 is then brought into contact with the Ga₂O₃-based melt 30 present in the opening 112b of the die 112 in a state that a horizontal position of the seed crystal 35 is offset in the width direction W from the center of the die 112 in the width direction W. In this regard, more preferably, the seed crystal 35 is brought into contact with the Ga₂O₃-based melt 30 covering the top surface of the die 112 in a state that the horizontal position of the seed crystal 35 is located at an edge of the die 112 in the width direction W.

Next, the seed crystal 35 in contact with the Ga₂O₃-based melt 30 is pulled vertically upward, thereby growing the β-Ga₂O₃-based single crystal 36.

The β-Ga₂O₃-based single crystal has high cleavability on the (100) plane, and twins with the (100) plane as a twinning plane (a plane of symmetry) are likely to be formed in the shoulder broadening process during crystal growth. Therefore, it is preferable to grow the β-Ga₂O₃-based single crystal 32 in a direction in which the (100) plane is parallel to the growth direction of the β-Ga₂O₃-based single crystal 32, e.g., to grow in a b-axis direction or a c-axis direction so as to allow the size of a crystal without twins cut from the β-Ga₂O₃-based single crystal 32 to be maximized.

It is especially preferable to grow the β-Ga₂O₃-based single crystal 32 in the b-axis direction since the β-Ga₂O₃-based single crystal is liable to grow in the b-axis direction.

In the meantime, in case that the growing β-Ga₂O₃-based single crystal is twinned during the process of broadening a shoulder in a width direction, twinning planes are likely to be formed in a region close to the seed crystal and are less likely to be formed at positions distant from the seed crystal.

The method of growing the β-Ga₂O₃-based single crystal 36 in the first embodiment uses such twinning properties of the β-Ga₂O₃-based single crystal. In the first embodiment, since the β-Ga₂O₃-based single crystal 36 is grown in the state that the horizontal position of the seed crystal 35 is offset in the width direction W from the center of the die 112 in the width direction W, a region far from the seed crystal 35 is large in the β-Ga₂O₃-based single crystal 36, as compared to the case of growing the β-Ga₂O₃-based single crystal 36 in a state that the horizontal position of the seed crystal 35 is located on the center of the die 112 in the width direction W. Twinning planes are less likely to be formed in such a region and it is thus possible to cut out a wide seed crystal 31.

For growing the β-Ga₂O₃-based single crystal 36 using the seed crystal 35 and for cutting the β-Ga₂O₃-based single crystal 36 into a seed crystal, it is possible to use a technique disclosed in JP-B-2013-102599.

Next, an example method of cutting the grown β-Ga₂O₃-based single crystal 32 into the β-Ga₂O₃-based single crystal substrate 1 will be described.

Firstly, the β-Ga₂O₃-based single crystal 32 having a thickness of, e.g., 18 mm is grown and is then annealed to relieve thermal stress during single crystal growth and to improve electrical characteristics. The annealing is performed, e.g., in an inactive atmosphere such as nitrogen while maintaining temperature at 1400 to 1600° C. for 6 to 10 hours.

Next, the seed crystal 31 and the β-Ga₂O₃-based single crystal 32 are separated by cutting with a diamond blade. Firstly, the β-Ga₂O₃-based single crystal 32 is fixed to a carbon stage with heat-melting wax in-between. The β-Ga₂O₃-based single crystal 32 fixed to the carbon stage is set on a cutting machine and is cut for separation. The grit number of the blade is preferably about #200 to #600 (defined by JIS B 4131) and a cutting rate is preferably about 6 to 10 mm per minute. After cutting, the β-Ga₂O₃-based single crystal 32 is detached from the carbon stage by heating.

Next, the edge of the β-Ga₂O₃-based single crystal 32 is shaped into a circular shape by an ultrasonic machining device or a wire-electrical discharge machine. Orientation flats may be formed at the edge of the circularly-shaped β-Ga₂O₃-based single crystal 32.

Next, the circularly-shaped β-Ga₂O₃-based single crystal 32 is sliced to about 1 mm thick by a multi-wire saw, thereby obtaining the β-Ga₂O₃-based single crystal substrate 1. In this process, it is possible to slice at a desired offset angle. It is preferable to use a fixed-abrasive wire saw. A slicing rate is preferably about 0.125 to 0.3 mm per minute. Next, the β-Ga₂O₃-based single crystal substrate 1 is annealed to reduce processing strain and to improve electrical characteristics as well as permeability. The annealing is performed in an oxygen atmosphere during temperature rise and is performed in an inactive atmosphere such as nitrogen atmosphere when maintaining temperature after the temperature rise. The temperature to be maintained here is preferably 1400 to 1600° C.

Next, the edge of the β-Ga₂O₃-based single crystal substrate 1 is chamfered (bevel process) at a desired angle.

Next, the β-Ga₂O₃-based single crystal substrate 1 is ground to a desired thickness by a diamond abrasive grinding wheel. The grit number of the grinding wheel is preferably about #800 to #1000 (defined by JIS B 4131).

Next, the β-Ga₂O₃-based single crystal substrate is polished to a desired thickness using a turntable and diamond slurry. It is preferable to use a turntable formed of a metal-based or glass-based material. A grain size of the diamond slurry is preferably about 0.5 μm.

Next, the β-Ga₂O₃-based single crystal substrate 1 is polished using a polishing cloth and CMP (Chemical Mechanical Polishing) slurry until atomic-scale flatness is obtained. The polishing cloth formed of nylon, silk fiber or urethane, etc., is preferable. Slurry of colloidal silica is preferably used. The main surface of the β-Ga₂O₃-based single crystal substrate 1 after the CMP process has a mean roughness of about Ra=0.05 to 0.1 nm.

(Evaluation of Semiconductor Multilayer Structure)

One of the features of the semiconductor multilayer structure 40 in the first embodiment is that dislocation density on the main surface 4 of the β-Ga₂O₃-based single crystal substrate 1 is low. The following is the evaluation result about the impact of the dislocation density of the main surface 4 of the β-Ga₂O₃-based single crystal substrate 1 on the surface state of the nitride semiconductor layer 42 formed on the main surface 4 by epitaxial crystal growth.

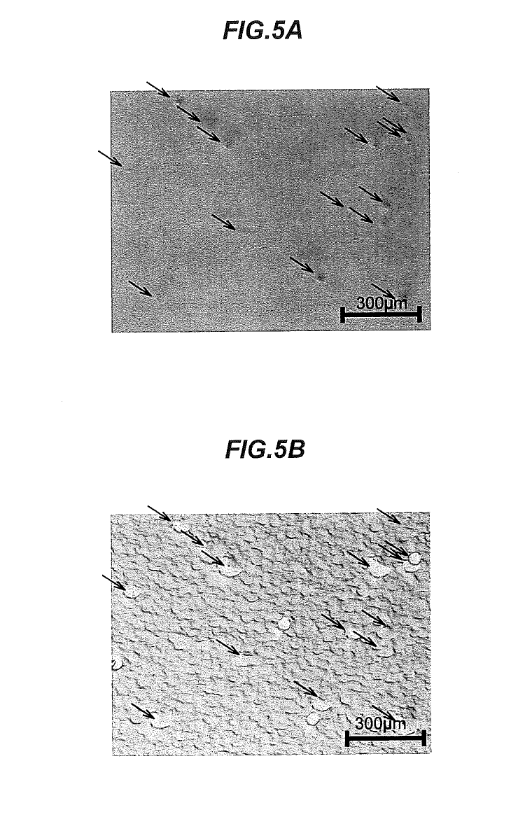

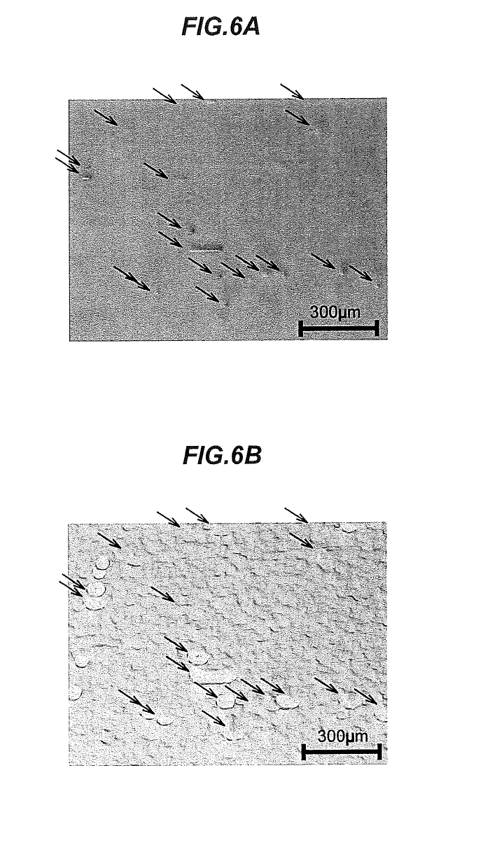

FIGS. 5A, 5B, 6A and 6B are optical microscope observation images showing a surface state of β-Ga₂O₃ single crystal substrates containing relatively many dislocations and a surface state of GaN layers epitaxially grown on main surfaces thereof. The dislocation density of the β-Ga₂O₃ single crystal substrate shown in FIG. 5A and that of the β-Ga₂O₃ single crystal substrate shown in FIG. 6A are respectively about 1.3×10³/cm² and about 1.7×10³/cm².

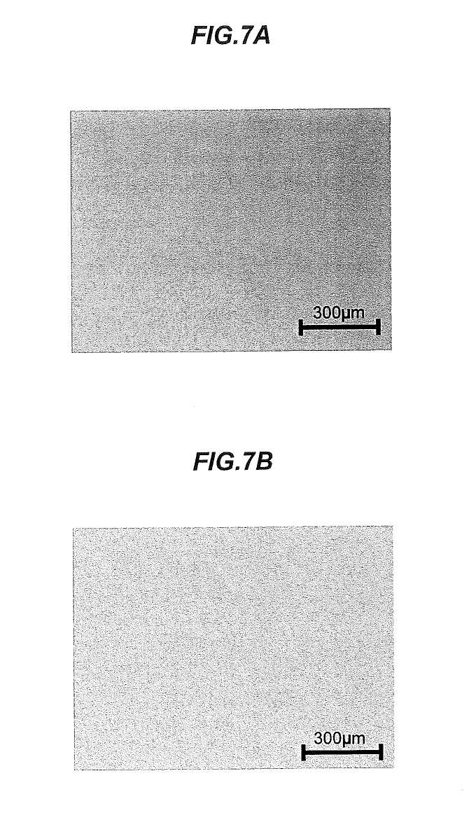

Meanwhile, FIGS. 7A and 7B are optical microscope observation images showing a surface state of a β-Ga₂O₃ single crystal substrate containing relatively less dislocations and a surface state of a GaN layer epitaxially grown on a main surface thereof. The dislocation density of the β-Ga₂O₃ single crystal substrate shown in FIG. 7A is not more than 1×10²/cm².

The β-Ga₂O₃ single crystal substrates are used as an example of the β-Ga₂O₃-based single crystal substrate 1 and the GaN layers are used as an example of the nitride semiconductor layer 42.

FIGS. 5A, 6A and 7A show the surface state of the respective β-Ga₂O₃ single crystal substrates, and the arrows in the drawings point to positions of main pit-type defects on the surfaces of the β-Ga₂O₃ single crystal substrates. Meanwhile, FIGS. 5B, 6B and 7B show the surface state of the respective GaN layers, and the arrows in the drawings point to positions of main hillock-type defects on the surfaces of the GaN layers.

FIGS. 5A, 5B, 6A and 6B show that hillock-type defects are formed on the surface of the GaN layer at the positions corresponding to pit-type defects on the surface of the β-Ga₂O₃ single crystal substrate. Meanwhile, FIGS. 7A and 7B show that hillock-type defects are not formed on the surface of the GaN layer in a region corresponding to a pit-type defect-free region of the surface of the β-Ga₂O₃ single crystal substrate.

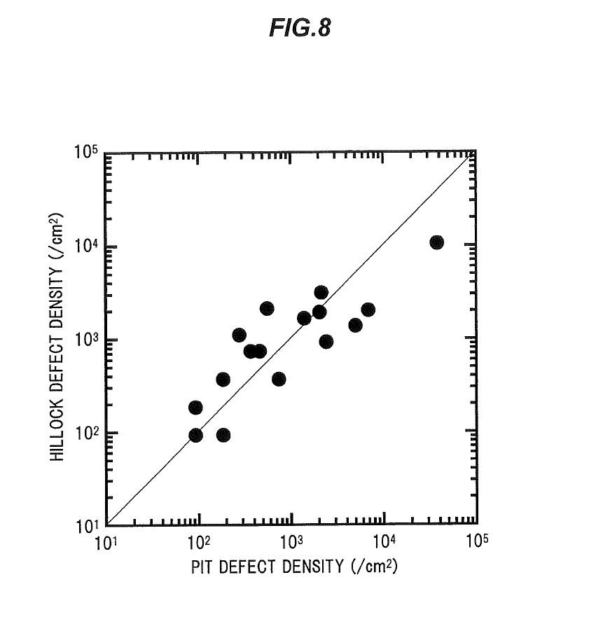

FIG. 8 is a graph showing a relation between a pit-defect density on a surface of the β-Ga₂O₃ single crystal substrate and a hillock-defect density on a surface of the GaN layer. In FIG. 8, the horizontal axis indicates a pit-defect density (/cm²) measured at the center of the surface of the β-Ga₂O₃ single crystal substrate and the vertical axis indicates a hillock-defect density (/cm²) measured at the center of the surface of the GaN layer.

FIG. 8 shows that the hillock-defect density on the surface of the GaN layer is substantially equal to the pit-defect density on the surface of the β-Ga₂O₃ single crystal substrate.

FIG. 8 also shows that the nitride semiconductor layer 42 with the hillock-defect density of not more than 1×10³/cm², which is suitable for manufacturing light-emitting elements or semiconductor elements such as transistor, is obtained. This is because, in the first embodiment, the β-Ga₂O₃-based single crystal substrate 1 obtained by the manufacturing method described above has a low dislocation density. The minimum pit-defect density on the surface of the β-Ga₂O₃ single crystal substrate shown in FIG. 8 is 92.6 (/cm²).

Next, the cross section of the β-Ga₂O₃ single crystal substrate with the GaN layer was observed using TEM (Transmission Electron Microscope) to evaluate pit-type defects on the surface of the β-Ga₂O₃ single crystal substrate and dislocations in the GaN layer.

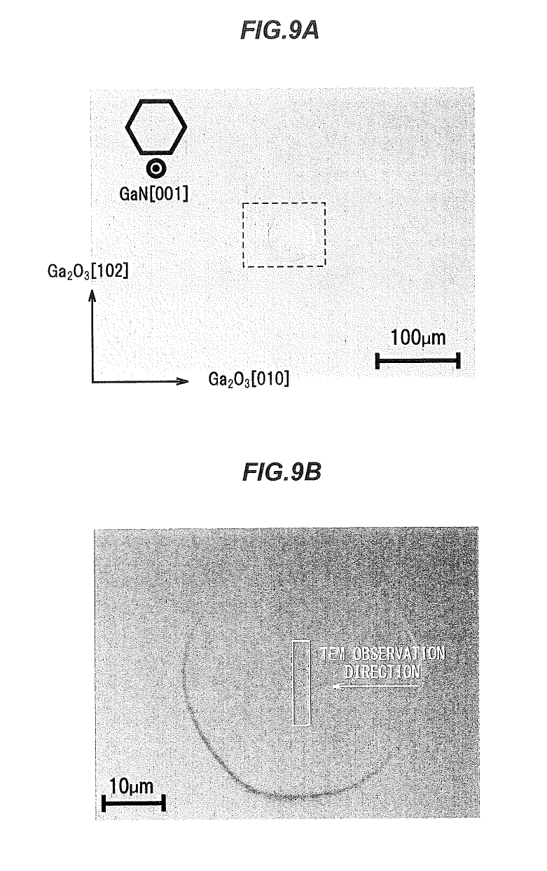

FIGS. 9A and 9B are optical microscope observation images showing a position on a surface of the GaN layer at which TEM observation is performed. FIG. 9B is an enlarged view of a portion indicated by a dotted line in FIG. 9A.

A circular raised portion shown in FIGS. 9A and 9B is a hillock-type defect on the surface of the GaN layer. A region including the center of the hillock-type defect (the region enclosed by a rectangle in FIG. 9B) was cut out and the cross section thereof was observed by TEM.

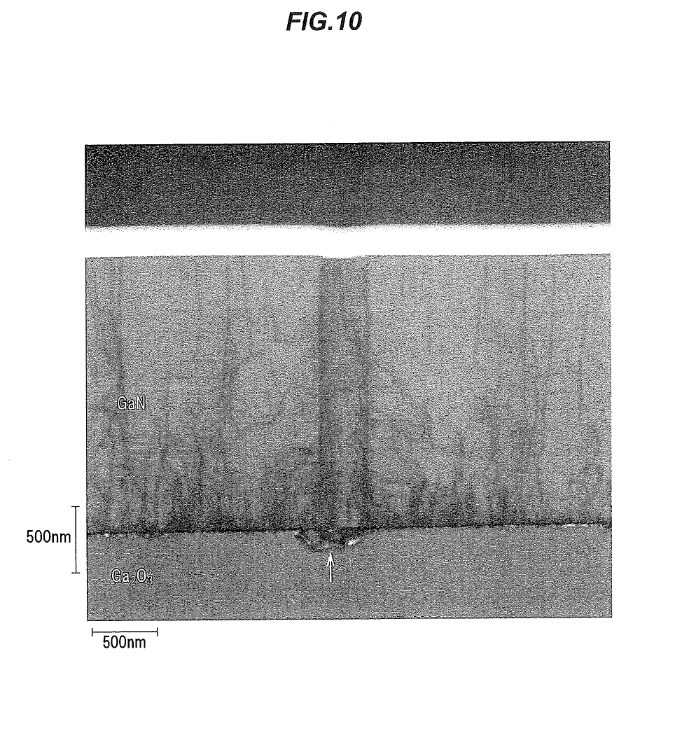

FIG. 10 is a TEM observed image showing a cross section of the β-Ga₂O₃ single crystal substrate with the GaN layer in the region shown in FIGS. 9A and 9B.

The arrow in FIG. 10 points to a position of a dent (pit-type defect) on the surface of the β-Ga₂O₃ single crystal substrate.

FIG. 10 shows that a pit-type defect is present on the surface of the β-Ga₂O₃ single crystal substrate directly under the center of the hillock-type defect and dense dislocations extend in the GaN layer directly above the pit-type defect. Dislocations are formed at an interface between the β-Ga₂O₃ single crystal substrate and the GaN layer and extend upward as the GaN layer grows. All of black portions in the GaN layer are dislocation portions. At this time, more dislocations are formed in a region directly above the pit-type defect than in a region therearound, as shown in FIG. 10. Therefore, crystal quality of the GaN layer in the region directly above the pit-type defects is especially poor.

### Second Embodiment

### Configuration of Semiconductor Element

The second embodiment is an embodiment of a semiconductor element including the semiconductor multilayer structure 40 in the first embodiment. An LED element will be described below as an example of such a semiconductor element.

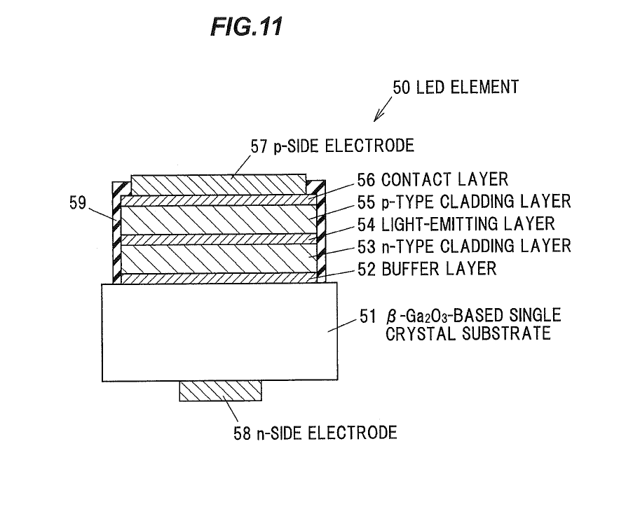

FIG. 11 is a vertical cross-sectional view showing an LED element 50 in the second embodiment. The LED element 50 has a β-Ga₂O₃-based single crystal substrate 51, a buffer layer 52 on the β-Ga₂O₃-based single crystal substrate 51, an n-type cladding layer 53 on the buffer layer 52, a light-emitting layer 54 on the n-type cladding layer 53, a p-type cladding layer 55 on the light-emitting layer 54, a contact layer 56 on the p-type cladding layer 55, a p-side electrode 57 on the contact layer 56 and an n-side electrode 58 on a surface of the β-Ga₂O₃-based single crystal substrate 51 opposite to the buffer layer 52.

Then, side surfaces of the laminate composed of the buffer layer 52, the n-type cladding layer 53, the light-emitting layer 54, the p-type cladding layer 55 and the contact layer 56 are covered with an insulating film 59.

Here, the β-Ga₂O₃-based single crystal substrate 51, the buffer layer 52 and the n-type cladding layer 53 are formed by respectively dividing or patterning the β-Ga₂O₃-based single crystal substrate 1, the buffer layer 41 and the nitride semiconductor layer 42 which constitute the semiconductor multilayer structure 40 in the first embodiment. The thicknesses of the β-Ga₂O₃-based single crystal substrate 51, the buffer layer 52 and the n-type cladding layer 53 are respectively, e.g., 400 μm, 5 nm and 5 μm.

Addition of a conductive impurity allows the β-Ga₂O₃-based single crystal substrate 51 to have conductivity and it is thereby possible to use the β-Ga₂O₃-based single crystal substrate 51 to form a vertical-type semiconductor device as is the LED element 50 in which electricity is conducted in a thickness direction. In addition, the β-Ga₂O₃-based single crystal substrate 51 is transparent to light in a wide range of wavelength. Therefore, in a light-emitting device as is the LED element 50, it is possible to extract light on the β-Ga₂O₃-based single crystal substrate 51 side.

The n-type cladding layer 53, which is formed of the nitride semiconductor layer 42 of the semiconductor multilayer structure 40, contains less hillock-type defects. Thus, the light-emitting layer 54, the p-type cladding layer 55 and the contact layer 56 which are formed on such an n-type cladding layer 53 by epitaxial growth also contains less defects. Therefore, the LED element 50 is excellent in leakage current characteristics, reliability and drive performance, etc.

The light-emitting layer 54 is composed of, e.g., three layers of multi-quantum-well structures and a 10 nm-thick GaN crystal film thereon. Each multi-quantum-well structure is composed of an 8 nm-thick GaN crystal film and a 2 nm-thick InGaN crystal film. The light-emitting layer 54 is formed by, e.g., epitaxially growing each crystal film on the n-type cladding layer 53 at a growth temperature of 750° C.

The p-type cladding layer 55 is, e.g., a 150 nm-thick GaN crystal film containing Mg at a concentration of 5.0×10¹⁹/cm³. The p-type cladding layer 55 is formed by, e.g., epitaxially growing a Mg-containing GaN crystal on the light-emitting layer 54 at a growth temperature of 1000° C.

The contact layer 56 is, e.g., a 10 nm-thick GaN crystal film containing Mg at a concentration of 1.5×10²⁰/cm³. The contact layer 56 is formed by, e.g., epitaxially growing a Mg-containing GaN crystal on the p-type cladding layer 55 at a growth temperature of 1000° C.

For forming the buffer layer 52, the n-type cladding layer 53, the light-emitting layer 54, the p-type cladding layer 55 and the contact layer 56, it is possible to use TMG (trimethylgallium) gas as a Ga raw material, TMI (trimethylindium) gas as an In raw material, (C₂H₅)₂SiH₂ (diethylsilane) gas as a Si raw material, Cp₂Mg (bis(cyclopentadienyl)magnesium) gas as a Mg raw material and NH₃ (ammonia) gas as an N raw material.

The insulating film 59 is formed of an insulating material such as SiO₂ and is formed by, e.g., sputtering.

The p-side electrode 57 and the n-side electrode 58 are electrodes in ohmic contact respectively with the contact layer 56 and the β-Ga₂O₃-based single crystal substrate 51 and are formed using, e.g., a vapor deposition apparatus.

The buffer layer 52, the n-type cladding layer 53, the light-emitting layer 54, the p-type cladding layer 55, the contact layer 56, the p-side electrode 57 and the n-side electrode 58 are formed on the β-Ga₂O₃-based single crystal substrate 51 (the β-Ga₂O₃-based single crystal substrate 1) in the form of wafer and the β-Ga₂O₃-based single crystal substrate 51 is then cut into chips of, e.g., 300 μm square in size by dicing, thereby obtaining the LED elements 50.

The LED element 50 is, e.g., an LED chip configured to extract light on the β-Ga₂O₃-based single crystal substrate 51 side and is mounted on a CAN type stem using Ag paste.

Although the LED element 50 which is a light-emitting element has been described as an example of a semiconductor element including the semiconductor multilayer structure 40 of the first embodiment, the semiconductor element is not limited thereto and may be other light-emitting elements such as laser diode or other elements such as transistor. Even when using the semiconductor multilayer structure 40 to form another element, it is also possible to obtain a high-quality element since layers formed on the semiconductor multilayer structure 40 by epitaxial growth have less defects in the same manner as the LED element 50.

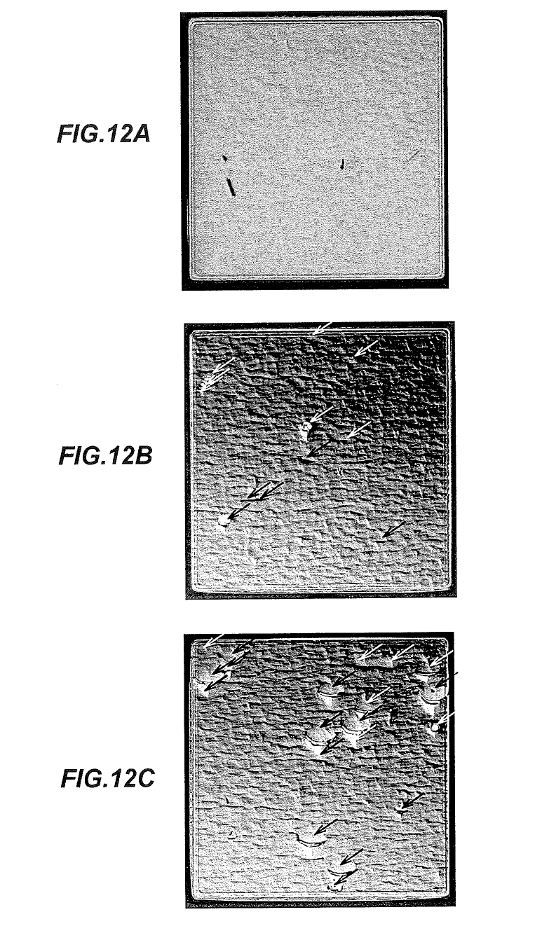

FIGS. 12A, 12B and 12C are optical microscope observation images of surfaces of LED elements, respectively showing an LED element 50 formed using a hillock-type defect-free region of the nitride semiconductor layer 42 (hereinafter, referred to as LED element 50a), an LED element 50 formed using a region with a few hillock-type defects (hereinafter, referred to as LED element 50b) and an LED element 50 formed using a region with many hillock-type defects (hereinafter, referred to as LED element 50c).

The arrows in the drawings point to positions of main hillock-type defects on the surfaces of the LED element 50b and 50c (the surface of the p-side electrode 57). The LED elements 50a, 50b and 50c have a square planar shape of 1 mm×1 mm. The hillock-defect densities of the LED element 50b and 50c are respectively 1.2×10³/cm² and 2.0×10³/cm². The β-Ga₂O₃-based single crystal substrate 51 of the LED elements 50a, 50b and 50c is not separated to chip size yet at the time of observation and the below-described leakage current measurement.

In the LED elements 50a, 50b and 50c, the β-Ga₂O₃-based single crystal substrate 51 is a 400 μm-thick β-Ga₂O₃ single crystal substrate, the buffer layer 52 is a 5 nm-thick AlN crystal layer, the n-type cladding layer 53 is a 5 μm-thick GaN crystal layer, the light-emitting layer 54 has a multi-quantum-well structure composed of an 8 nm-thick GaN crystal film and a 2 nm-thick InGaN crystal film, the p-type cladding layer 55 is a 150 nm-thick GaN crystal layer, the contact layer 56 is a 10 nm-thick GaN crystal layer, the p-side electrode 57 has a structure formed by laminating a 500 nm-thick Ag film, a 1 μm-thick Pt film and a 3 μm-thick AuSn film, and the n-side electrode 58 has a structure formed by laminating a 50 nm-thick Ti film and a 1 μm-thick Au film.

Current values (magnitude of leakage current) when applying forward voltage of 2.0V between the p-side electrode 57 and the n-side electrode 58 were 3.1 μA for the LED element 50a, 126 μA for the LED element 50b and not less than 1000 μA (equal to or greater than the measurement limit of a measuring device) for the LED element 50c. In addition, when the light-emitting state of the LED elements 50a, 50b and 50c was checked, the LED elements 50a and 50b emitted light but the LED element 50c did not emit light.

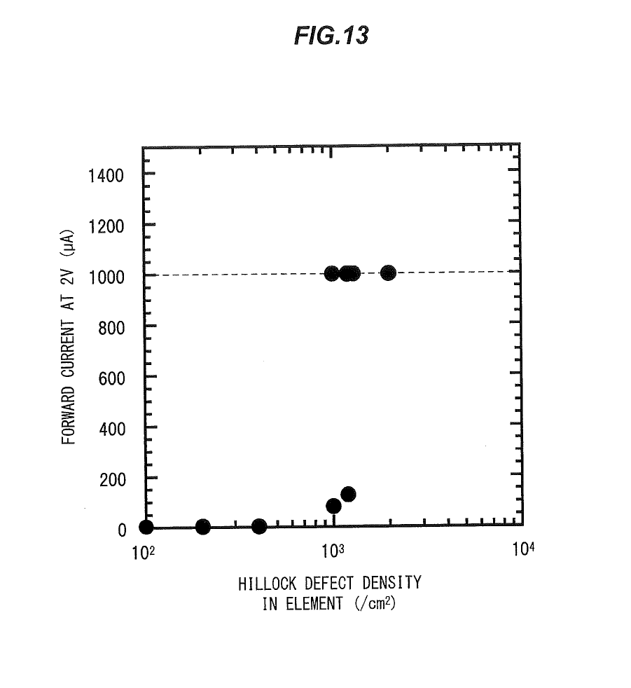

FIG. 13 is a graph showing a relation between hillock-defect density and magnitude of leakage current in the LED element 50 which has the same structure as the LED elements 50a, 50b and 50c. In FIG. 13, the horizontal axis indicates a hillock-defect density (/cm²) in the LED element 50 and the vertical axis indicates magnitude of leakage current (μA) when forward voltage of 2.0V is applied between the p-side electrode 57 and the n-side electrode 58. The dotted line in the drawing indicates the limit of the measuring device to measure leakage current.

FIG. 13 shows that leakage current sharply increases when the hillock-defect density in the LED element 50 exceeds 1×10³/cm². The hillock-defect density in the LED element 50 is substantially equal to the dislocation density of the β-Ga₂O₃-based single crystal substrate 51. Therefore, the LED element 50 excellent in performance and reliability is obtained when the dislocation density of the β-Ga₂O₃-based single crystal substrate 51 is not more than 1×10³/cm².

### Effects of the Embodiments

In the first embodiment, by processing a high-quality β-Ga₂O₃-based single crystal with less dislocations which is grown using a growth method described in the first embodiment, it is possible to obtain a β-Ga₂O₃-based single crystal substrate with low dislocation density and excellent crystal quality. In addition, by epitaxially growing a nitride semiconductor crystal on such a β-Ga₂O₃-based single crystal substrate with low dislocation density, it is possible to form a nitride semiconductor layer with low hillock-defect density and excellent crystal quality and thereby to obtain a high-quality semiconductor multilayer structure.

In the second embodiment, use of the high-quality semiconductor multilayer structure obtained in the first embodiment allows high-quality crystal films to be epitaxially grown thereon and it is thereby possible to obtain a high-performance semiconductor element with high crystal quality.

It should be noted that the invention is not intended to be limited to the embodiments and the various kinds of modifications can be implemented without departing from the gist of the invention.

In addition, the invention according to claims is not to be limited to embodiments. Further, it should be noted that all combinations of the features described in the embodiments are not necessary to solve the problem of the invention.

What is claimed is:

1. A semiconductor multilayer structure, comprising:
a β-Ga₂O₃-based single crystal substrate comprising a dislocation density on a main surface of not more than 1×10³/cm²; and
a nitride semiconductor layer comprising an AlₓGa_{y}In_{z}N (0≦x≦1, 0≦y≦1, 0≦z≦1, x+y+z=1) crystal epitaxially grown on the β-Ga₂O₃-based single crystal substrate.

2. The semiconductor multilayer structure according to claim 1, further comprising a buffer layer comprising an AlₓGa_{y}In_{z}N (0≦x≦1, 0≦y≦1, 0≦z≦1, x+y+z=1) crystal between the β-Ga₂O₃-based single crystal substrate and the nitride semiconductor layer.

3. The semiconductor multilayer structure according to claim 1, wherein the nitride semiconductor layer comprises a GaN crystal.

4. The semiconductor multilayer structure according to claim 2, wherein the nitride semiconductor layer comprises a GaN crystal.

5. A semiconductor element, comprising:
the semiconductor multilayer structure according to claim 1.

6. A semiconductor element, comprising:
the semiconductor multilayer structure according to claim 2.

7. A semiconductor element, comprising:
the semiconductor multilayer structure according to claim 3.

8. A semiconductor element, comprising:
the semiconductor multilayer structure according to claim 4.
